(19) United States
(12) Patent Application Publication
(10) Pub. No.: US 2016/0141228 A1
(43) Pub. Date: May 19, 2016

(54) DEVICE CONNECTION THROUGH A BURIED OXIDE LAYER IN A SILICON ON INSULATOR WAFER

(71) Applicant: International Business Machines Corporation, Armonk, NY (US)

(72) Inventor: Effendi Leobandung, Stormville, NY (US)

(21) Appl. No.: 14/968,155

(22) Filed: Dec. 14, 2015

Related U.S. Application Data
(62) Division of application No. 14/541,277, filed on Nov. 14, 2014.

(51) Int. Cl. H01L 23/48; H01L 23/00

(52) U.S. Cl. CPC H01L 23/481; H01L 24/05; H01L 2224/02372

(57) ABSTRACT

An approach to forming a semiconductor structure for a semiconductor device with connections through a buried oxide layer in a silicon on insulator wafer. A buried oxide layer is formed on a semiconductor substrate and at least one semiconductor device is formed on the buried oxide layer. Additionally, a dielectric layer is deposited on the buried oxide layer and the at least one semiconductor device. At least one via is created from the at least one semiconductor device through the buried oxide layer. Furthermore at least one through silicon via is formed through the semiconductor substrate electrically connected to the at least one via from the dielectric layer through the buried oxide layer.

### BACKGROUND OF THE INVENTION

The present invention relates generally to the field of semiconductor technology, and more particularly to silicon on insulator wafers with vias through the buried oxide layer connected to semiconductor devices and through silicon vias.

In the manufacture of integrated circuits, there is a continuing desire to fit more semiconductor devices and circuits on semiconductor wafers. The drive for miniaturization and increasing circuit density is driven by a number of factors, including device speed, as denser circuits are closer together for fast communication, wafer utilization (more circuits per wafer) and potential semiconductor chip cost reduction as the number of semiconductor chips per wafer increase. With miniaturization and the desire for increasing circuits per wafer, more interconnections between circuit devices and external 110 may be required. Increasing interconnection wiring including the number of interconnection wiring layers and vias connecting interconnection wiring layers may drive more layers in the back end of the line (BEOL) to complete device circuit connections.

One manufacturing method for creating wafers and semiconductor chips with the ability to aide in miniaturization is use of silicon-on-insulator (SOI) wafers. SOI wafers provide layers of silicon separated by a buried insulation layer such as silicon dioxide. In addition to providing opportunities for additional wafer real estate, SOI wafers provide the opportunity for improved electrical performance, such as lower parasitic capacitance and reduced resistance to latch up. The semiconductor devices fabricated in the layer of silicon, which is above a layer of electrical insulating material such as SiO₂, experience improved semiconductor device isolation and performance.

SOI wafers may be created by several processes. An oxygen implantation using a high temperature anneal process which may be called Separation by Implantation of Oxygen (SIMOX) is commonly used to form SOI wafers. Separation by Implantation of Nitrogen (SIMON) is also sometimes used to create SOI wafers. Another commonly used process to create a SOI wafer is the bonding of two wafers together, one of which has an insulating or oxide layer or other dielectric material layer which is then sandwiched between the wafers. The wafers, at least one of which is covered by the insulating or oxide layer, may be bonded by adhesive, or fusion bonded if both surfaces are covered with an oxide layer. In some applications where a thinner wafer is desired for device formation, a wafer cutting or separation process followed by a wafer surface polish may be used. SOI wafers provide improved performance and opportunities to utilize additional available wafer space created with an SOI structure. The processes involved in the manufacture of SOI wafers are consistent with semiconductor manufacturing tools and thus require little investment to implement.

### SUMMARY

Embodiments of the present invention provide a method of fabricating a semiconductor device with connections through a buried oxide layer in a silicon on insulator wafer. The method includes forming a buried oxide layer on a semiconductor substrate and forming at least one semiconductor device on the buried oxide layer. Additionally, the method includes depositing a dielectric layer on the buried oxide layer and the at least one semiconductor device and, forming at least one via from the dielectric layer to the at least one semiconductor device and through the buried oxide layer. Furthermore, the method includes forming at least one through silicon via through the semiconductor substrate electrically connected to the at least one via from the dielectric layer through the buried oxide layer.

The semiconductor structure for a semiconductor device on a silicon on insulator wafer includes a semiconductor substrate with one or more through silicon vias (TSV) through the semiconductor substrate. The semiconductor structure also includes a buried oxide layer on the semiconductor substrate with at least one semiconductor device on the buried oxide layer. Additionally, a dielectric layer is over the buried oxide layer and the at least one semiconductor device. Furthermore, the semiconductor structure includes at least one via through the buried oxide layer and the dielectric layer electrically connected to the at least one semiconductor device and the one or more TSV.

### BRIEF DESCRIPTION OF THE DRAWINGS

FIG. 1 depicts a cross-sectional view of a SOI wafer after fabrication steps to form semiconductor devices in accordance with an embodiment of the present invention.

FIG. 2 depicts a cross-sectional view of the SOI wafer after fabrication steps to etch vias to device contacts in accordance with an embodiment of the present invention.

FIG. 3 depicts a cross-sectional view of the SOI wafer after fabrication steps to etch vias through a buried insulating layer in accordance with an embodiment of the present invention.

FIG. 4 depicts a cross-sectional view of the SOI wafer after fabrication steps for via filling accordance with an embodiment of the present invention.

FIG. 5 depicts a cross-sectional view of the SOI wafer after fabrication steps to form redistribution wiring layers and a thin substrate in accordance with an embodiment of the present invention.

FIG. 6 depicts a cross-sectional view of the SOI wafer after fabrication steps to form a through silicon via in accordance with an embodiment of the present invention.

FIG. 7 depicts a cross-sectional view of the SOI wafer after fabrication steps to remove a carrier wafer in accordance with an embodiment of the present invention.

### DETAILED DESCRIPTION

Detailed embodiments of the claimed structures and methods are disclosed herein. The method steps described below do not form a complete process flow for manufacturing integrated circuits. The present embodiments can be practiced in conjunction with the integrated circuit fabrication techniques currently used in the art, and only so much of the commonly practiced process steps are included as are necessary for an understanding of the described embodiments. The figures represent cross-section portions of a semiconductor chip or a substrate during fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment”, etc., indicate that the embodiment described may include a particular feature, structure or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “over”, “on”, “positioned on” or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

In the interest of not obscuring the presentation of the embodiments of the present invention, in the following detailed description, some of the processing steps or operations that are known in the art may have been combined together for presentation and for illustration purposes and in some instances may not have been described in detail. In other instances, some processing steps or operations that are known may not be described. It should be understood that the following description is rather focused on the distinctive features or elements of the various embodiments of the present invention.

Embodiments of the present invention recognize that increasing circuit density may require a large number of wiring interconnect layers to escape device I/O connections to a wafer surface. The increasing level of backend of the line (BEOL) redistribution wiring layers and via connections create higher resistance in the device circuit escape path. Additionally, surface area on the wafer for increasing I/O escapes is limited. This is especially true for array area I/O connections utilizing metal bump or ball connections such as controlled collapse chip connections (C4's).

Embodiments of the present invention propose the use of SOI wafers with back-side last through silicon via (TSV) connected to a metal filled via extending through the buried insulating or oxide layer in the SOI wafer. The use of an SOI wafer with a TSV connected to a metal filled via that extends through the buried insulating layer, commonly a buried oxide layer or BOX, provides the electrical advantages inherent to SOI technology, in addition to lower resistance I/O escape. The use of TSV for device connections to the wafer surface provides shorter paths and lower resistance than traditional BEOL interconnect wiring layers. Additionally, an SOI wafer with TSV connections on the bottom of the semiconductor device may preserve top surface wafer semiconductor device area.

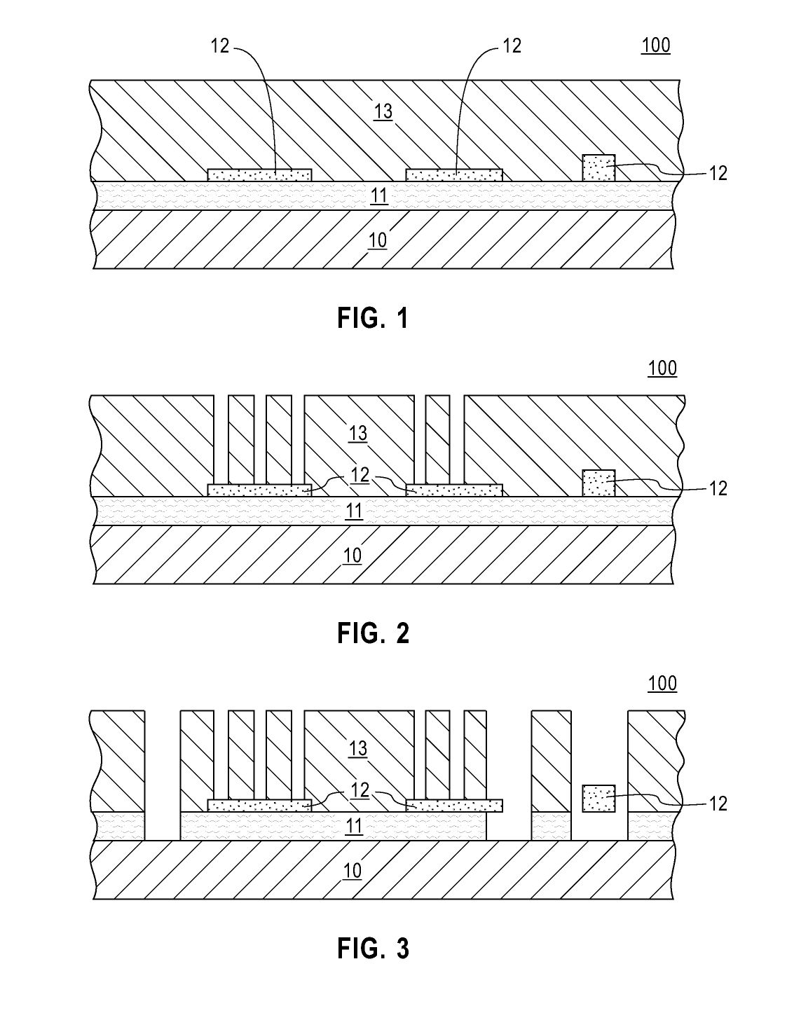

FIG. 1 depicts a cross-sectional view of SOI wafer 100 after fabrication steps to form semiconductor devices in accordance with an embodiment of the present invention. As depicted, FIG. 1 includes SOI wafer 100, substrate 10, BOX 11, semiconductor device(s) 12, and dielectric layer 13. Semiconductor devices such as semiconductor device(s) 12 may be formed on BOX 11.

SOI wafer 100 has a buried insulating layer identified as BOX 11. In an exemplary embodiment, the wafer used for SOI wafer 100 is formed using a SIMOX process. A SIMOX process uses oxygen implantation and a high temperature anneal to form a buried insulating layer or BOX 11 in the wafer. A wafer thinning or separation process, familiar to one skilled in the art, may be used to thin the top wafer surface for semiconductor device formation. In another embodiment, SOI wafer 100 of FIG. 1, may be formed from any suitable SOI process for SOI wafer formation. For example, SOI wafer 100 may be formed by joining two wafers, one of which has an oxide layer, together with a known adhesive or bonding process. In another example, SOI wafer 100 could be formed by fusion bonding of wafers with the same external insulating material layer such as silicon dioxide. In yet another example, SOI wafer 100 may be formed by a SIMON SOI wafer process (e.g. ion implantation of a nitrogen rich layer to form a buried insulating layer). In an embodiment, an ultra-thin layer of silicon may be used in SOI wafer 100. In another embodiment, an ultra-thin BOX 11 may be used in SOI wafer 100. SOI wafer 100 may be formed by any known SOI wafer process and known SOI wafer materials, and is not intended to be limited to the examples discussed above. In one embodiment, the buried insulating layer is composed of another SOI insulating material. For example, sapphire may be used for the buried insulating layer (i.e. BOX 11).

Substrate 10 is a semiconductor substrate. In the exemplary embodiment, substrate 10 is a single crystal silicon substrate. In another embodiment, substrate 10 may be composed of any suitable semiconductor material compatible with the SOI processes and TSV formation. For example, substrate 10 may be composed of SiGe, Ge, GaAs, any suitable group IV semiconductor or compound semiconductor material, any suitable group III-IV semiconductor material such as alloys of GaAlAs, InGaAs, InAlAs, InAlAsSb, InAlAsP, or InGaAsP. A group IV semiconductor material refers to the location of the semiconductor element in a column of the Periodic Table of Elements. Similarly, a group III-V semiconductor material refers to a semiconductor material that includes at least one element or material from group III and at least one element or material from group V of the Periodic Table of Elements. Substrate 10 may be composed of a low defect density semiconductor material which may be a single crystal, an amorphous, or a polycrystalline semiconductor. Substrate 10 may be doped, undoped, or contain doped or undoped regions. Substrate 10 may be strained, unstrained or a combination thereof.

BOX 11 is a buried insulating layer over substrate 10 on which semiconductor device(s) 12 may be formed. In the exemplary embodiment, the buried insulating layer, which is BOX 11, is composed of silicon dioxide. BOX 11 may be composed of any suitable insulating material used in the insulating layer between the semiconductor layers of a SOI wafer. For example, BOX 11 may be SiN, another nitride material, another oxide material or any other appropriate material for forming an insulating layer in a SOI wafer. In one embodiment, the thickness of BOX 11 is in the range 0.2 μm to 1 μm. In one embodiment, BOX 11 thickness may be greater than one micron and range to 10 μm. In another embodiment of the present invention, BOX 11 may be less than 0.2 μm.

In the exemplary embodiment, semiconductor device(s) 12 are formed on the buried insulating layer (i.e. BOX 11). Semiconductor device(s) 12 may be formed on BOX 11 using known, conventional processes including semiconductor element doping (i.e. for source, drain, channel, gate or similar device element formation) and silicon etch. Conventional processes for doping may include ion implantation. In another embodiment, using known wafer processes, semiconductor device(s) 12 may be formed on the top surface of a wafer bonded to substrate 10 covered by an layer of silicon dioxide to form SOI wafer 100.

The semiconductor devices depicted as device(s) 12 may be one or more of any type of semiconductor device or a combination of different semiconductor devices whose manufacturing process is compatible with SOI technology including SOI processes. For example, the depicted semiconductor devices labelled device(s) 12 may be complementary metal oxide semiconductor (CMOS) devices, field effect transistors (FET) including metal oxide semiconductor FET (MOSFET), finFET and other FETs, gates, bipolar devices, nanowire or nanotechnology devices, capacitors, any passive semiconductor devices, any logic semiconductor devices, or combination of semiconductor devices compatible with SOI technology. Device(s) 12 can also be formed from any semiconductor material such as Si, Ge, GaAS, SiGe, InGaAs, HgTe or any suitable semiconductor material. For example, device 12 may be formed from a group IV semiconductor material, a group III-V semiconductor material, or a group II-VI semiconductor material.

Dielectric layer 13 is formed on top of BOX 11 and semiconductor device(s) 12. Dielectric layer 13 may be composed of any suitable dielectric material or interlayer dielectric (ILD) material deposited by known methods such as chemical vapor deposition (CVD), atomic layer deposition (ADL), physical vapor deposition (PVD), or other appropriate dielectric material deposition process. In the exemplary embodiment, dielectric layer 13 is composed of silicon dioxide. In other embodiments, dielectric layer 13 may be composed of SiN, Si₃O₄, SiON, or any other suitable dielectric material. In the exemplary embodiment, dielectric layer 13 thickness may be in the range 0.1 μm to 10 μm however, the thickness of dielectric layer 13 is not limited to this thickness. The thickness of dielectric layer 13 may be determined by the type of devices used and device height and/or electrical performance requirements of the application.

FIG. 2 depicts a cross-sectional view of SOI wafer 100 after the fabrication steps to etch vias to device contacts in accordance with an embodiment of the present invention. As depicted, FIG. 2 includes the elements of FIG. 1 where a portion of dielectric layer 13 is removed to form via holes which extend from the top surface of dielectric layer 13 to the semiconductor device(s) 12 contacts. In the exemplary embodiment, an anisotropic etch process is used from the top surface of dielectric layer 13 to device contacts on semiconductor device(s) 12 however, any suitable etch process may be used to form vias through the dielectric to semiconductor device(s) 12. The anisotropic etch through dielectric layer 13 to semiconductor device(s) 12 contacts may be, for example, a reactive ion etch (RIE) process or an anisotropic wet etch process using conventional lithography processes.

FIG. 3 depicts a cross-sectional view of SOI wafer 100 after the fabrication steps to etch vias through the buried insulating layer in accordance with an embodiment of the present invention. As depicted, FIG. 3 includes the elements of FIG. 2 after another portion of dielectric layer 13 is removed and after a portion of BOX 11 is removed. The portions of dielectric layer 13 and BOX 11 removed by conventional etch processes form via holes to substrate 10. The via holes formed through dielectric 13 and BOX 11 may be formed by a one-step etch process or a two-step etch process. A one-step etch process selectively removes both dielectric layer 13 and BOX 11, stopping at the top surface of substrate 10. A two-step etch process may include a first etch of dielectric layer 13 followed by a second etch process to remove BOX 11. The via holes formed through the buried insulating layer of BOX 11 and dielectric layer 13 when filled after further processing of SOI wafer 100 may connect to the TSV vias.

In the exemplary embodiment, the via holes through BOX 11 and dielectric layer 13 are formed by an isotropic etch process terminating on substrate 10. For example, an isotropic wet etch process or any other known isotropic etch process suitable for an SOI wafer may be used to form the via holes through BOX 11 and dielectric layer 13. As depicted in FIG. 2, an isotropic etch process may remove dielectric material from one, two, three or all four surfaces or sides of semiconductor device(s) 12. In one embodiment, an anisotropic etch may be used removing dielectric material only from the top surface of semiconductor device(s) 12 exposed to the etching process and the side or edge of semiconductor device(s) 12 (e.g. no undercut below or round the device element). In another embodiment, a combination of anisotropic and isotropic processes may be used to form the via holes through BOX 11 and dielectric layer 13. The etch processes are not intended to be limited to the above processes and may be any suitable etch process for the dielectric material of dielectric layer 13 and the insulating material or dielectric material used in BOX 11 which is unreactive or inert to silicon or other semiconductor materials.

In the exemplary embodiment, the via holes through BOX 11 and dielectric layer 13 may have a diameter in the range of 30 nm to 100 nm. In other embodiments, the via holes through BOX 11 and dielectric layer 13 may be smaller than 10 nm or larger than 500 nm as determined by the device designer based on device electrical requirements and manufacturing process capabilities. In the exemplary embodiment, the via holes through BOX 11 and dielectric layer 13 may include or connect to a semiconductor device. As depicted, the via holes may connect semiconductor device(s) 12 to the TSV while some via holes may be from semiconductor device(s) 12 through dielectric layer 13. In later processes, when TSV are formed and the via holes are filled, a direct path is created for semiconductor device(s) 12 to the wafer surface.

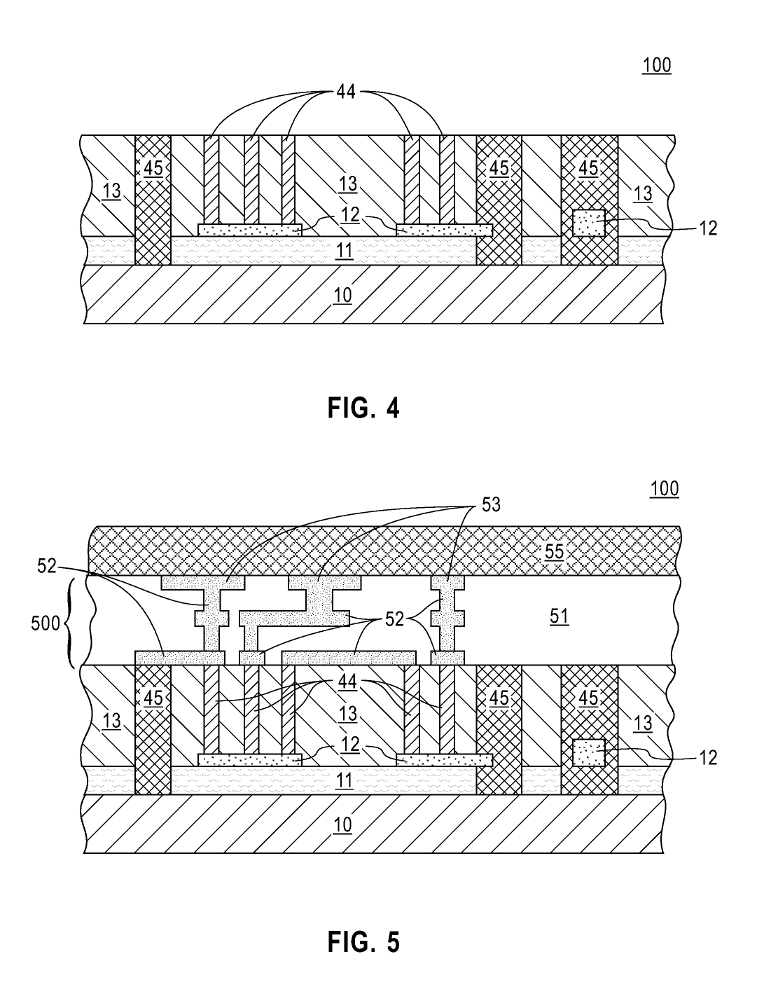

FIG. 4 depicts a cross-sectional view of SOI wafer 100 after the fabrication steps for via fill in accordance with an embodiment of the present invention. As depicted, FIG. 4 includes the elements of FIG. 3 and the metal used to fill the vias previously created in the steps of FIG. 2 and FIG. 3. Using known via fill processes and materials, vias 44 extending from the top surface of dielectric layer 13 through dielectric layer 13 to semiconductor device(s) 12 are filled with any suitable electrically conductive via fill material. In the exemplary embodiment, vias 44 and vias 45 are metal filled with tungsten however, in other embodiments, copper may be used. In the exemplary embodiment, vias 45 extending from the top of dielectric layer 13 through dielectric layer 13 and BOX 11 to the top surface of substrate 10 may be filled at the same time using the same processes as may be used to fill vias 44. In another embodiment, vias 45 may be filled at a different time than vias 44 and may be filled with a different electrically conductive material or a different combination of electrically conductive materials in the case of a layer via fill process. In an embodiment, vias 44 and 45 may be filled using a known layered via fill process (i.e. a seed layer and/or a via liner followed by a metal via fill). For example, a layer of TiN may be deposited with conventional processes followed by tungsten for via fill or in another example, a seed layer such as Ta, TaN, or Ti while tungsten and copper may be used for via fill. Via fill processes may include CVD, PVD, plasma enhanced vapor deposition, wet plating, or any suitable via fill process for an SOI wafer. In the exemplary embodiment, vias 45 extending through dielectric layer 13 and the buried dielectric layer of BOX 11 will connect with the TSV formed in later process steps.

FIG. 5 depicts a cross-sectional view of SOI wafer 100 after the fabrication steps to form redistribution wiring layers and a thin substrate in accordance with an embodiment of the present invention. As depicted, FIG. 5 includes the elements of FIG. 4, and redistribution layers 500, including BEOL lines and vias forming BEOL interconnects 52, ILD 51 and external pads 53 composed of one or more dielectric material layers used in the BEOL processes. Additionally, as depicted in FIG. 5, carrier wafer 55 is attached to SOI wafer 100 using conventional methods prior to backside wafer grind to thin substrate 10. Redistribution layers 500 include BEOL interconnects 52 and ILD 51 formed with conventional BEOL processes and materials such as tungsten or copper for redistribution interconnects, which include redistribution wiring and vias comprising BEOL interconnects 52, and interlayer dielectric materials as SiO2 or any other suitable dielectric material used in BEOL processes for redistribution of semiconductor device(s) 12 I/O and power connections. Redistribution layers 500 include external pads 53 which may be used for connection to the next level of semiconductor packaging. Vias 44 may connect device(s) 12 to redistribution layers 500. In an embodiment, vias 44 and vias 45 connect directly with external pads 53 when no redistribution layers are present. The connection to next level packaging on external pads 53 may be any known interconnection method such as solder, wire bond, conductive adhesive, fusion bonding, and thermal compression bonding which may connect to a first level package such as a ceramic substrate, another semiconductor chip, wafer, or other electronic device.

In the exemplary embodiment, carrier wafer 55 which is a carrier wafer may be bonded using conventional wafer bonding adhesive or other bonding method to the top of redistribution layers 500. The carrier wafer may be used for handling and stability when a backside wafer grind is performed on substrate 10. In another embodiment, SOI wafer 100 does not include a carrier wafer.

In the exemplary embodiment, SOI wafer 100 with carrier wafer 55 bonded is thinned using traditional wafer backside grind processes. The backside grind of substrate 10 in SOI wafer 100 reduces the thickness of substrate 10 providing the opportunity for lower aspect ratio TSV when TSV are completed due reduced semiconductor substrate thickness of substrate 10. The aspect ratio of a via is the thickness of a substrate divided by the via hole size extending through the substrate. In addition, the reduced thickness of substrate 10 provides a shortened path for electrical connections upon completion of TSVs (e.g. provides potential for a slight reduction of signal speed in semiconductor device(s) 12).

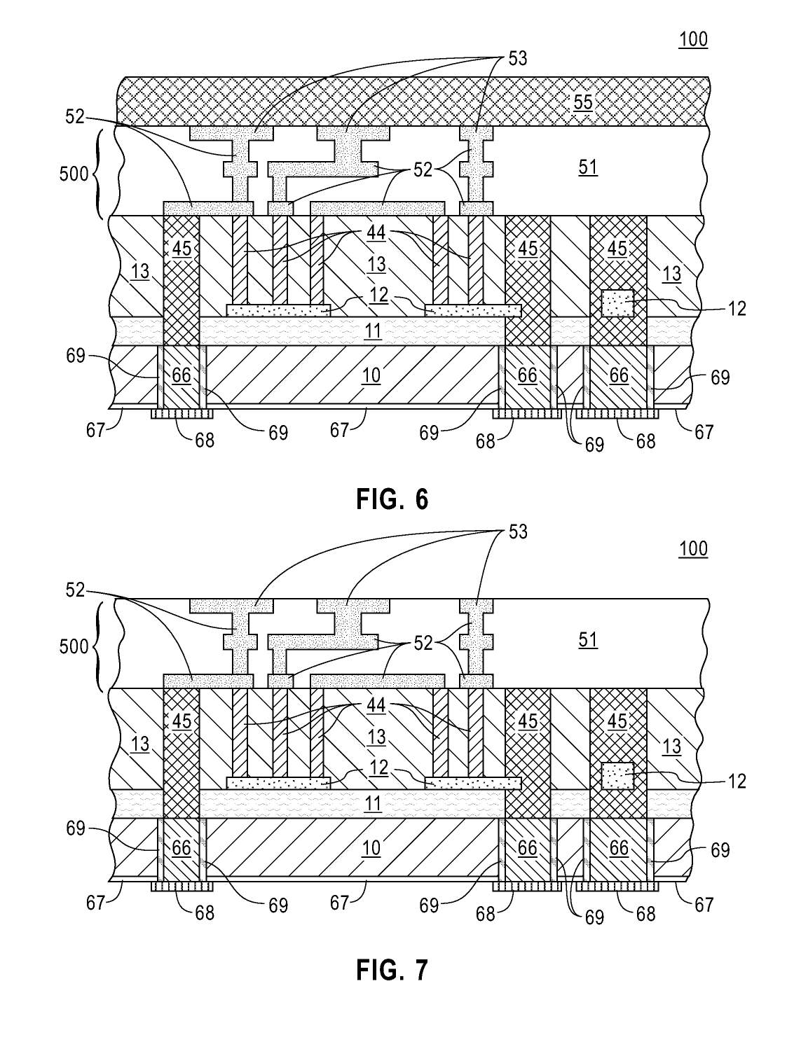

FIG. 6 depicts a cross-sectional view of SOI wafer 100 after the fabrication steps to form TSV in accordance with an embodiment of the present invention. As depicted, FIG. 6 includes the elements of FIG. 5 and TSV 66, dielectric layer 67, TSV pads 68, and TSV isolation layer 69. In the exemplary embodiment, TSV 66 is formed by a backside via-last process in which TSV formation is one of the last steps in SOI wafer 100 fabrication. In another embodiment, TSV 66 may be formed before vias 44 and 45. In one embodiment, TSV 66 may be formed before redistribution layers 500 while in yet another embodiment, TSV 66 may be formed before semiconductor device(s) 12. TSV 66 may be formed with known processes for through semiconductor or through silicon via formation. TSV 66 formation may include a via etch using a selective, deep silicon reactive ion etch, for example. A deep silicon reactive ion etch chamber may be used to etch vias for TSV formation. Etching the vias may be a one, a two or a multi-step process depending on the depth required for the TSVs and the materials used in the SOI wafer structure. In the exemplary embodiment, TSV 66 formation includes a selective, single step silicon etch process for via etch through substrate 10 terminating at vias 45. TSV isolation layer 69 may be a dielectric material such as a nitride or oxide material deposited by a known process such as CVD, for example. The dielectric material for TSV isolation layer 69 may be deposited in the via for TSV 66. TSV isolation layer 69 may provide passivation to TSV 66 to electrically isolate the via in TSV 66. In one embodiment, TSV 66 may not have TSV isolation layer 69. Since TSV 66 stop on BOX 11 or in other words, do not extend beyond the buried oxide layer, semiconductor device(s) 12 can be built on top of TSV 66 which saves real estate on the wafer (i.e. SOI wafer 100). In the exemplary embodiment, vias 45 connect to semiconductor device(s) 12 to TSV 66 and connect TSV 66 to redistribution layers 500. In one embodiment, vias 45 electrically connect external pads 53 on the top surface of SOI wafer 100 to semiconductor device(s) 12 through BOX 11 to TSV 66.

TSV 66 vias are filled with a conductive material. TSV 66 may include a liner such as Ta, TaN, TaN over Ta, or any suitable liner material and a seed layer such as copper or Ta for via metal fill processes. In the exemplary embodiment, TSV 66 is filled with a metal fill such as copper. The metal fill may be deposited in a TSV plating chamber. In another embodiment, TSV 66 may be filled with any suitable electrically conductive material, for example, tungsten. In an embodiment, a chemical mechanical polish may be performed after TSV 66 via fill to complete TSV 66.

In the exemplary embodiment, the bottom surface of substrate 10 is covered with a layer of dielectric material, dielectric layer 67. The dielectric material may be silicon dioxide or other known dielectric material such as polyimide or spin on glass deposited by known conventional processes. In an embodiment, dielectric layer 67 may be deposited in the via for TSV 66, etched from the bottom of the via, and used as TSV isolation layer 69.

In the exemplary embodiment, TSV pads 68 composed of an electrically conductive material which are formed on the external surface of TSV 66 using known deposition and patterning processes. In the exemplary embodiment, TSV pads 68 may be composed of copper deposited by CVD. In other embodiments, TSV pads 68 may composed of another metal which may be deposited with another process. For example, TSV 66 may be composed of tungsten and other deposition processes may include PVD, ALD or a wet chemical plating process.

TSV pads 68 may be used to connect SOI wafer to another level of semiconductor packaging such as a first level package which may be a ceramic chip carrier, a PCB, another semiconductor wafer including another SOI wafer as may be done for three dimensional semiconductor wafer stacking, or one or more semiconductor chips. Interconnections for TSV pads 68 to the next level of packaging or wafer may be accomplished by any known connection process. For example, the connections of TSV pads 68 to another level of packaging may be done using one or more of the following: wafer bumping, controlled collapse chip connections (C4's), wiring bonding, fusion bonding, conductive adhesive bonding, or any other semiconductor I/O connection process or interconnection method. In one embodiment, vias 45 may connect TSV 66 to redistribution layers 500 and/or external pads 53.

FIG. 7 depicts a cross-sectional view of the SOI wafer after the fabrication steps to remove carrier wafer 55 in accordance with an embodiment of the present invention. As depicted, FIG. 7 includes the elements of FIG. 6 except for carrier wafer 55. In the exemplary embodiment, carrier wafer 55 is removed from SOI wafer 100 using known wafer de-bonding methods. With the removal of carrier wafer 55, external pads 53 may be used for interconnection to the next level of packaging, another electronic device, or to connect to another semiconductor wafer or semiconductor chip. In an embodiment, carrier wafer 55 may remain on SOI wafer 100.

In some embodiments, the SOI wafers formed by the embodiments of the present invention may be diced in semiconductor chip form. The resulting semiconductor chips can be distributed by the fabricator in raw wafer form (that is, as a single wafer that has multiple unpackaged chips), as a bare die or in a packaged form. In the latter case, the chip is mounted in a single chip package (such as a plastic carrier, with lead that is affixed to a motherboard or other higher level carrier) or in a multichip package (such as a ceramic carrier that has either or both surface interconnections or buried interconnections). In any case the chip is then integrated with other chips, discreet circuit elements, motherboard or (b) end product. The end product can be any product that includes integrated circuit chips, ranging from toys and other low-end applications to advanced computer products having a display, a keyboard or other input device and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A semiconductor device on a silicon on insulator (SOI) wafer, comprising:
a semiconductor substrate;
one or more through silicon vias (TSV) through the semiconductor substrate;
a buried oxide layer on the semiconductor substrate;
at least one semiconductor device on the buried oxide layer;
a dielectric layer over the buried oxide layer and the at least one semiconductor device; and
at least one via through the buried oxide layer and the dielectric layer electrically connected to the at least one semiconductor device and the one or more TSV.

2. The semiconductor device of claim 1, further comprising one or more redistribution layers formed on the dielectric layer and electrically connected to the at least one via.

3. The semiconductor device of claim 1, includes at least one TSV pad for electrical connection to one or more of the following: a semiconductor wafer, a semiconductor chip, and a first level package.

4. The semiconductor device of claim 1, wherein the at least one via is electrically connected to the semiconductor device on more than two sides of the semiconductor device.

5. The semiconductor device of claim 1, wherein the semiconductor device is at least one of an active device or a passive device.

6. The semiconductor device of claim 1, wherein the semiconductor device may be composed of at least one of the following: a group IV semiconductor material, a group III-V semiconductor material, and a group II-VI semiconductor material.

7. The semiconductor device of claim 1, wherein the one or more TSV include a dielectric layer for electrical isolation of the TSV.
